(19) United States
(12) Patent Application Publication
(10) Pub. No.: US 2013/0237040 A1
(43) Pub. Date: Sep. 12, 2013

(54) RESIN COMPOSITION, LAMINATE AND PROCESS FOR PRODUCTION THEREOF, STRUCTURE AND PROCESS FOR PRODUCTION THEREOF, AND PROCESS FOR PRODUCTION OF ELECTRONIC DEVICE

(71) Applicant: ASAHI GLASS COMPANY, LIMITED, Chiyoda-ku (JP)

(72) Inventor: Junichi KAKUTA, Tokyo (JP)

(73) Assignee: ASAHI GLASS COMPANY, LIMITED, Chiyoda-ku (JP)

(21) Appl. No.: 13/866,492

(22) Filed: Apr. 19, 2013

Related U.S. Application Data
(63) Continuation of application No. PCT/JP2011/074047, filed on Oct. 19, 2011.

(30) Foreign Application Priority Data
Oct. 19, 2010 (JP) 2010-234924

(51) Int. Cl. H01L 21/02

(52) U.S. Cl. CPC H01L 21/02422
USPC 438/479; 528/26; 525/422; 428/355 R; 427/207.1

(57) ABSTRACT

The present invention relates to a resin composition containing: a polyimide silicone which has, in a silicone moiety therein, a crosslinking site at which a crosslinking reaction occurs upon heating at a second temperature, in which the crosslinking reaction proceeds by heating a third temperature that exceeds the second temperature further than the second temperature; and a solvent which vaporizes upon heating at a first temperature that is lower than the second temperature.

### TECHNICAL FIELD

The present invention relates to a resin composition, a laminate and a process for producing the same, a structure and a process for producing the same, and a process for producing an electronic device.

### BACKGROUND ART

Thinning and weight saving have been required for electronic devices such as display panels such as a liquid crystal panel (LCD), a plasma panel (PDP), and an organic EL panel (OLED), a solar cell, and a thin film secondary battery, and thus, thinning of a substrate to be used for these electronic devices have been progressing. When rigidity of the substrate decreases due to thinning, handling ability of the substrate get worse. In addition, when thickness of the substrate changes due to thinning, it becomes difficult to manufacture the electronic devices by using existing facilities.

As the substrate, a glass substrate has been hitherto used but, recently, a resin substrate has been considered. However, since the resin substrate has a remarkably low rigidity as compared with the glass substrate, a decrease in handling ability of the substrate is prone to be a problem.

Thus, there has been proposed a method of attaching a reinforcing plate to a resin substrate, forming at least a part of constituent members (for example, thin-film transistor, etc.) constituting an electronic device on the substrate, and subsequently peeling off the reinforcing plate from the substrate (for example, see Patent Document 1). According to the method, the handling ability of the substrate can be secured and a thin electronic device can be manufactured by using existing facilities.

As the reinforcing plate, a laminate having a resin layer detachable from the substrate and a fixing plate that fixes the resin layer is employed. As a peeling operation for peeling the laminate from the substrate, it is performed by inserting a razor or the like into one part between the substrate and the resin layer to make a gap and then separating the substrate side from the fixing plate side. Here, the resin layer is required to have a performance of preventing the substrate from positional shifting until the peeling operation is carried out and also of easily being peeled off from the substrate at the time of the peeling operation. When peeling cannot be performed easily, the resin layer undergoes cohesive failure and attaches to the substrate side, which is to be a product, in some cases. Moreover, when peeling cannot be performed easily, the substrate is sometimes damaged. Furthermore, since the resin layer is heated during the producing steps of electronic devices, it is required to have a performance that it is less prone to undergo thermal deterioration. When the resin layer foams upon heating and a gas accumulates between the resin layer and the substrate, unintended exfoliation or deformation is caused.

The resin layer described in Patent Document 1 comprises a cured product of a silicone resin composition and is, for example, constituted by a crosslinking reaction product of a linear polyorganosiloxane having a vinyl group and methylhydrogene polysiloxane having a hydrosilyl group. It is described that the resin layer has a high heat resistance and also shows non-adhesiveness so as to be easily peeled off from the substrate by a peeling operation.

### RELATED ART

### Patent Document

Patent Document 1: JP-A-2007-326358

### SUMMARY OF THE INVENTION

### Problems that the Invention is to Solve

Since a cured product of a silicone resin composition shows non-adhesiveness, in the case of a laminate in which the silicone resin composition is used as a resin layer, its attachment to a substrate is insufficient and positional shifting of the substrate cannot be prevented in some cases. Particularly, in the case where the substrate is a resin, the attachment is prone to be insufficient and hence a resin layer having a high adhesive property is required.

Accordingly, in order to enhance the adhesive property of the resin layer, it has been proposed to add a silicone having adhesiveness to a silicone resin composition. However, there is a disadvantage that heat resistance of the resin layer decreases as the amount thereof to be added increases.

The present invention is devised in view of the above problem and an object thereof is to provide a resin composition capable of forming a resin layer excellent in adhesive property and heat resistance.

In order to solve the above problem, the present invention provides the following invention.

### Means for Solving the Problems

[1] A resin composition comprising: a polyimide silicone having, in a silicone moiety therein, a crosslinking site at which a crosslinking reaction occurs upon heating at a second temperature that exceeds a first temperature; and a solvent which vaporizes upon drying at the first temperature that is lower than the second temperature.
[2] The resin composition according to [1], in which the polyimide silicone has a crosslinking group as the crosslinking site.
[3] The resin composition according to [2], in which the crosslinking group is an alkenyl group having an unsaturated double bond at a terminal thereof.
[4] The resin composition according to [3], in which the resin composition further comprises a peroxide that forms a radical upon heating up to the first temperature and

the crosslinking group is a crosslinking site at which crosslinking occurs in the presence of the radical.

[5] The resin composition according to [2], in which the crosslinking group is an alkoxysilyl group and is a crosslinking site at which crosslinking occurs through a condensation reaction upon heating at the second temperature.
[6] The resin composition according to [1], in which the polyimide silicone has a crosslinking point as the crosslinking site,

the resin composition further comprises a peroxide that forms a radical upon heating at the second temperature, and

the crosslinking point is a site at which crosslinking occurs in the presence of the radical.

[7] The resin composition according to [6], in which the crosslinking point is an alkyl group that is bonded to a silicon atom.
[8] A laminate comprising a resin layer and a fixing plate that fixes the resin layer,

in which the resin layer is obtained by heating the resin composition described in any one of [1] to [7] at the first temperature and drying it.

[9] A process for producing a laminate containing a resin layer and a fixing plate that fixes the resin layer, which comprises

a step of forming the resin layer by heating the resin composition described in any one of [1] to [7] at the first temperature and drying it.

[10] A process for producing a structure containing a substrate, a resin layer that supports the substrate and a fixing plate that fixes the resin layer, which comprises

a step of forming the resin layer by heating the resin composition described in any one of [1] to [7] at the first temperature and drying it.

[11] A process for producing an electronic device comprising: a forming step of forming at least a part of constituent members constituting the electronic device on the substrate of the structure obtained by the producing process described in [10]; and a removing step of removing the resin layer and the fixing plate by peeling off the resin layer from the substrate on which the at least a part of constituent members is formed,

in which, in the forming step, the resin layer is heated up to a third temperature that exceeds the second temperature and the crosslinking site of the polyimide silicone is crosslinked.

[12] A process for producing an electronic device comprising:

a step of applying on a fixing plate a resin composition comprising a polyimide silicone having a crosslinking site in a silicone moiety therein and a solvent, and

subsequently heating them at a first temperature to volatilize the solvent, to obtain a laminate comprising the fixing plate and a resin layer,

a step of heating at a second temperature that exceeds the first temperature, to obtain a laminate in which the resin layer is crosslinked,

a step of laminating a substrate on the resin layer side of the laminate in which the resin layer is crosslinked, to obtain a structure comprising the substrate, the resin layer that supports the substrate and the fixing plate that fixes the resin layer,

a forming step of heating up to a third temperature that exceeds the second temperature to cause crosslinking the crosslinking site of the polyimide silicone and to form at least a part of structural members constituting the electronic device on the substrate of the structure, and

a removing step of removing the resin layer and the fixing plate by peeling off the resin layer from the substrate on which the at least a part of structural members is formed, in this order.

[13] A process for producing an electronic device comprising:

a step of laminating on a fixing plate a resin layer obtained by heating a resin composition comprising a polyimide silicone having a crosslinking site in a silicone moiety therein and a solvent at a first temperature to volatilize the solvent, to obtain a laminate comprising the fixing plate and the resin layer,

a step of heating at a second temperature that exceeds the first temperature, to obtain a laminate in which the resin layer is crosslinked,

a step of laminating a substrate on the resin layer side of the laminate, to obtain a structure comprising the substrate, the resin layer that supports the substrate and the fixing plate that fixes the resin layer,

a forming step of heating up to a third temperature that exceeds the second temperature to cause crosslinking the crosslinking site of the polyimide silicone and to form at least a part of structural members constituting the electronic device on the substrate of the structure, and

a removing step of removing the resin layer and the fixing plate by peeling off the resin layer from the substrate on which the at least a part of structural members is formed, in this order.

### Advantage of the Invention

According to the present invention, it is possible to provide a resin composition capable of forming a resin layer excellent in adhesive property and heat resistance.

### BRIEF DESCRIPTION OF THE DRAWINGS

FIG. 1 is a side view of a structure according to one embodiment of the present invention.

### MODE FOR CARRYING OUT THE INVENTION

The present invention is not limited to the embodiments to be mentioned below and various modifications and changes can be added to the embodiments to be mentioned below without departing from the scope of the invention.

### (Resin Composition)

The resin composition of the present invention is a liquid mixture containing a solvent that vaporizes upon heating at a first temperature (hereinafter also referred to as T1) and a polyimide silicone that has, in a silicone moiety therein, a crosslinking site at which a crosslinking reaction occurs upon heating at a second temperature (hereinafter also referred to as T2, and T1<T2) that exceeds the first temperature.

The resin composition forms a resin layer (the resin layer means a layer-shaped solid formed from a resin obtained upon vaporization of the solvent from the resin composition).

The first temperature is a temperature at which the solvent contained in the resin composition is vaporized. The first temperature is set depending on the kind of the solvent in the resin composition and is preferably set to a temperature about 10° C. to 20° C. higher than the boiling point (the boiling point is a boiling point at the pressure under heating (drying) conditions) of the solvent since drying time can be decreased to a short period of time.

The second temperature is a temperature at which the crosslinking site undergoes a crosslinking reaction and is a temperature at which crosslinking substantially proceeds. The second temperature is preferably a temperature lower than a third temperature (hereinafter also referred to as T3) at which the resin layer is heated in the producing step of an electronic device to be mentioned below (that is, T1<T2<T3).

The third temperature depends on the kind of the producing steps of an electronic device but, for example, in the case of forming an amorphous silicon layer that is a part of a thin-film transistor (TFT), it is preferably about 350° C. and the holding time at the third temperature is preferably about 1 hour.

In the case of an oxide semiconductor, it is preferred that the third temperature is 400° C. or higher and the holding time at the third temperature is 1 hour or more.

### (Solvent)

The solvent contained in the resin composition of the present invention is preferably a solvent that dissolves the polyimide silicone. As examples of the solvent, use can be made of methyl ethyl ketone (MEK, boiling point: 80° C.), methyl isobutyl ketone (MIBK, boiling point: 116° C.), butyl acetate (boiling point: 126° C.), propylene glycol monomethyl ether acetate (PGMEA, boiling point: 146° C.), cyclohexanone (boiling point: 156° C.), dimethylacetamide (DMAc, boiling point: 165° C.), N-methylpyrrolidone (NMP, boiling point: 202° C.), and the like.

The amount of the solvent is preferably an amount in which the concentration of the polyimide silicone in the resin composition becomes 1 to 50% by weight and is particularly preferably an amount in which it becomes 25 to 50% by weight.

The boiling point of the solvent in the present invention is not particularly limited but it is preferably from 50 to 230° C. since the drying time can be decreased to a short period of time.

### (Polyimide Silicone (S))

The polyimide silicone (hereinafter also referred to as polyimide silicone (S)) in the present invention is a copolymer of a polyimide with a silicone macromonomer and is a compound having both of heat resistance of a polyimide and flexibility of a silicone. Furthermore, the polyimide silicone (S) has a crosslinking site in a silicone moiety therein. The term “having a crosslinking site in a silicone moiety” means that a group capable of forming a crosslinking site is bonded directly or indirectly through a linking group to a silicon atom forming the chain of a siloxane. The silicone macromonomer is preferably a diaminosiloxane from a standpoint of reactivity with a polyimide monomer.

The polyimide silicone (S) of the present invention has a crosslinking site at which a crosslinking reaction occurs upon heating at the second temperature, in a silicone moiety therein. The term “crosslinking site” means a group capable of forming a new chemical bond between the polyimide silicones in the present invention or a group capable of forming a new chemical bond between the polyimide silicone and another compound capable of crosslinking with the polyimide silicone. In the present invention, the former group is preferred. When the silicone moiety is crosslinked, flexibility decreases and adhesive property decreases. Moreover, when the silicone moiety is crosslinked, since thermal decomposition of the silicone moiety is suppressed and generation of low molecular gases (e.g., cyclic siloxanes) is suppressed, heat resistance increases. With the progress of the crosslinking reaction, the polyimide silicone becomes high molecular weight.

The polyimide silicone may have a crosslinking group or a crosslinking point as the crosslinking site.

As the crosslinking site in the present specification, a known group capable of undergoing the crosslinking reaction can be adopted.

As the crosslinking group, there may be mentioned an alkenyl group having an unsaturated double bond at a terminal thereof, an alkoxysilyl group, and the like. Particularly, as the alkenyl group having an unsaturated double bond at a terminal thereof, there may be mentioned a vinyl group or an alkenyl group having 3 or more carbon atoms which has a vinyl group at a terminal thereof, and a vinyl group is preferred. The vinyl group moiety forms a chemical bond of —CH₂—CH₂—CH₂—CH₂— upon crosslinking at a temperature of 230° C. or higher.

As the alkoxysilyl group, a trialkoxysilyl group in which the carbon number of the alkoxy moiety is from 1 to 6 is preferred from the standpoint of the easiness of occurrence of the crosslinking reaction, and trimethoxysilyl group or triethoxysilyl group is particularly preferred. The alkoxysilyl group undergoes a condensation reaction upon heating at the second temperature to form a chemical bond (Si—O—Si).

In the case where the crosslinking site is a crosslinking group, the number of the crosslinking groups in the polyimide silicone is preferably from 30% to 200% and more preferably from 50% to 150% of the total number of silicon atoms in the silicone moiety (moiety in which —SiO— is ranged). When the number of the crosslinking groups falls within the range, crosslinking is prone to occur, hardness of the formed resin layer is appropriate, and gas generation can be suppressed.

The crosslinking point in the present specification means a site that does not usually undergo a crosslinking reaction but can change into a crosslinking group by an action of another component in the resin composition.

In the case where the crosslinking site is a crosslinking point, for example, an alkyl group may be mentioned. An alkyl group can change into an alkyl radical in the presence of a radical and a plurality of the alkyl radicals can undergo a crosslinking reaction with each other. For example, in the case where the crosslinking point is a methyl group, a chemical bond of —CH₂—CH₂— is formed through the crosslinking reaction. The carbon number of the alkyl group as the crosslinking point is preferably from 1 to 8 from the standpoint of the easiness of occurrence of the crosslinking reaction.

The polyimide silicone in the present invention is preferably a compound having a vinyl group, an alkoxysilyl group, or an alkyl group as the crosslinking site and particularly preferably a compound having a vinyl group. In the case where the vinyl groups are crosslinked with each other, there is an advantage that a liquid or gas such as water or an alcohol is not generated. Also, in the case where the crosslinking among the vinyl groups are carried out in the presence of a radical, there is an advantage that a liquid or gas is not generated since the radical is introduced into the molecule of the polyimide silicone.

The crosslinking group or crosslinking point present in the polyimide silicone of the present invention may be each only one species or two or more species but is ordinary preferably only one species. In the case of two or more species, for example, in the case where both of the vinyl group and the alkyl group are present, the vinyl groups are more promptly crosslinked with each other than the alkyl groups.

Specific examples of the polyimide silicone (S) will be described.

The polyimide silicone (S) is preferably a compound essentially having a structure represented by the formula (1).

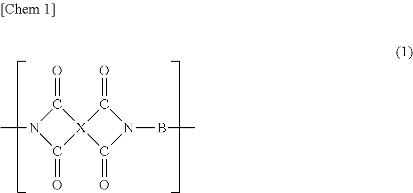

X in the formula (1) represents a tetravalent organic group and includes the groups specifically represented in the following formulae. B represents a silicone moiety having a crosslinking site, and groups specifically represented as the repeating units (B1), (B2), and (B3) to be mentioned below are preferred.

The polyimide silicone (S) is preferably a compound in which the structures represented by the formula (1) are ranged or a compound in which the structures represented by the formula (1) and structures obtained by replacing the B moiety in the structural formula (1) with a silicone moiety B′ having no crosslinking site are ranged.

As the polyimide silicone (S), preferred are a compound in which B in the formula (I) is a group (B1) having an alkenyl group, a compound in which B is a group (B2) having an alkoxysilyl group, or a compound containing a group (B3) having no crosslinking group and having an alkyl group bonded to a silicon atom. The following will describe them in sequence.

[Polyimide Silicone (S1) in which B is a Group (B1) Having Alkenyl Group]

The polyimide silicone (S1) has a repeating unit in which B is a silicone moiety (B1) having an alkenyl group in the above formula (1), and the repeating unit is represented by the following formula (s1). X in the formula (s1) is the same as X in the formula (s1-1) to be mentioned below, including preferred embodiments. The polyimide silicone (S1) is preferably a compound having a repeating unit of the silicone moiety (B1) having an alkenyl group and the other repeating unit. The compositional formula of the compound is represented by the formula (s1-1).

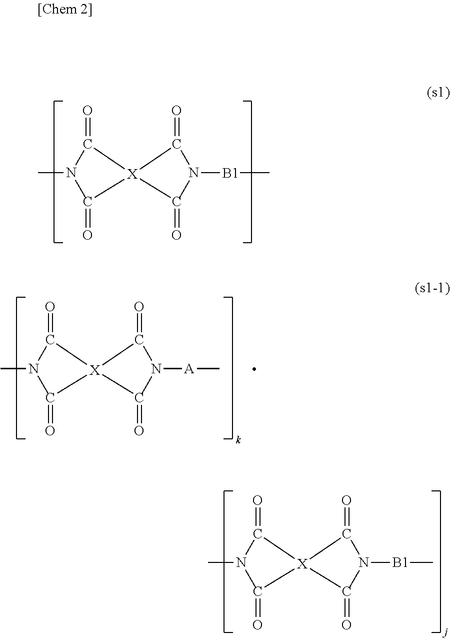

k and j in the formula (s1-1) represent ratios of a repeating unit containing A and a repeating unit containing B1 contained therein. k is a numeral of 0≦k<1 and j is a numeral of 0<j≦1; and k+j=1. In the formula (s1-1), preferably k is 0.3≦k≦0.7 and j is 0.3≦j≦0.7; further preferably k is 0.4≦k≦0.6 and j is 0.4≦j≦0.6; and particularly preferably k is 0.5 and j is 0.5.

In the representation of the formula (s1-1), the repeating unit containing A and the repeating unit containing B1 may be ranged block-wise or may be ranged randomly. A block-wise ranging moiety may be included in a randomly ranging moiety. In a similar representation in the other formula, the meanings of the ranging of repeating units are the same.

X in the formula (s1-1) is a tetravalent organic group. A plurality of the X's in the formula (s1-1) may be the same or different and is preferably the same. X is preferably any of the following groups.

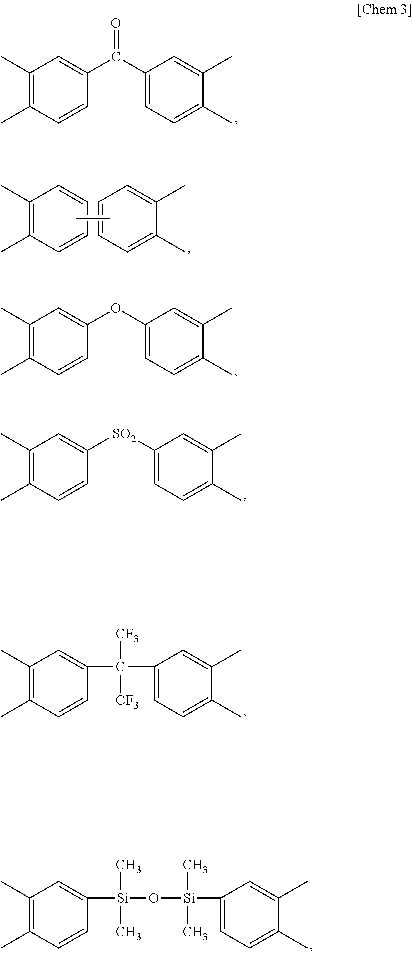

The repeating unit containing A in the formula (s1-1) is a repeating unit containing no crosslinking site. A in the formula (s1-1) is a divalent group and is preferably a group represented by the following formula (a1).

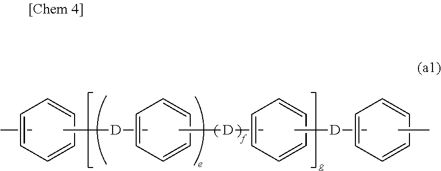

In the case where A is the formula (a1), D's in the formula (a1) are divalent organic groups containing no crosslinking site and are preferably each independently any of the following groups. e, f, and g are 0 or 1.

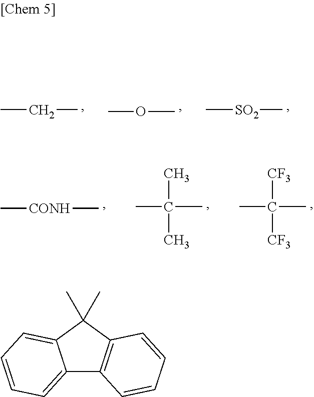

Specific examples in the case where A is a group represented by the formula (a1) and is a group having two aromatic rings in its main chain include the following groups.

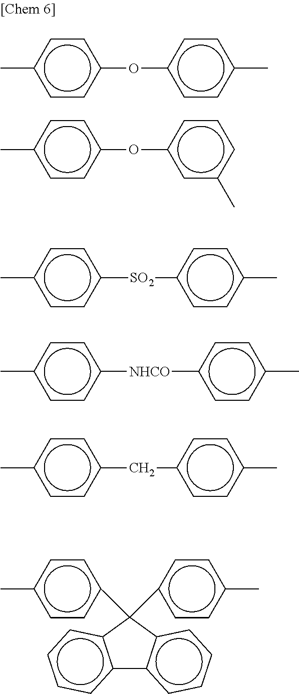

Specific examples in the case where A is a group represented by the formula (a1) and is a group having three aromatic rings in its main chain include the following groups.

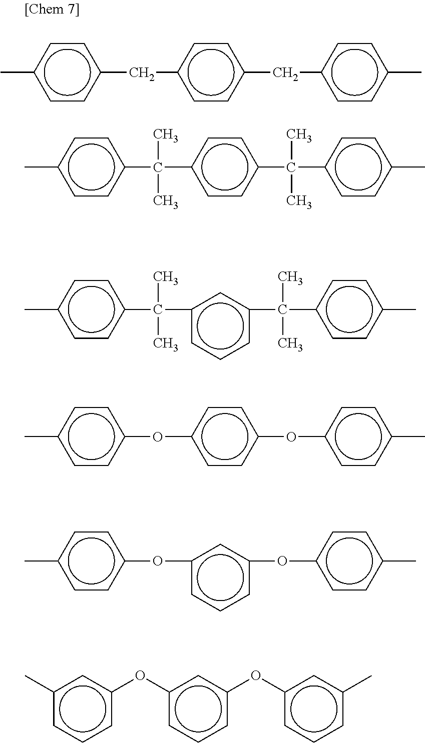

Specific examples in the case where A is a group represented by the formula (a1) and is a group having four aromatic rings in its main chain include the following groups.

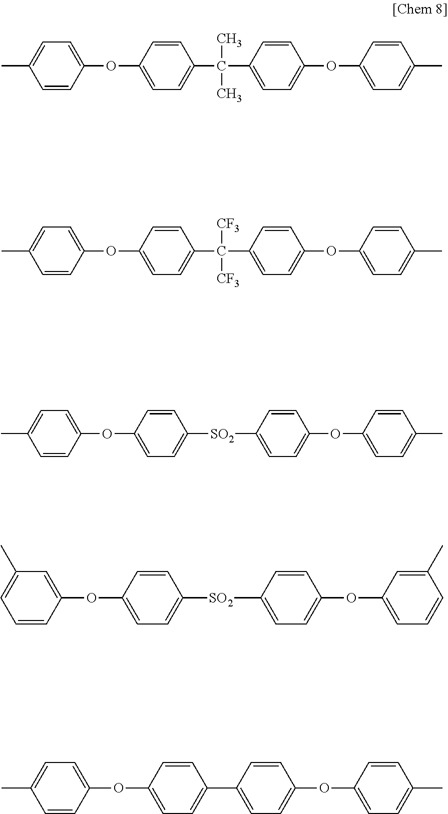

In the case where A is the formula (a1), the repeating unit containing A can be obtained though a reaction of a diamine compound having two or more aromatic rings and two amino groups with a tetracarboxylic acid compound (anhydride) having the X group.

The diamine compound includes the following compounds: compounds having two amino groups such as 4,4′-diaminodiphenyl ether, 4,4′-diaminodiphenyl sulfone, 4,4′-diaminodiphenyl sulfide, 2,2-bis(4-aminophenoxyphenyl)propane, 2,2-bis(4-aminophenoxyphenyl)sulfone, 2,2-bis(3-aminophenoxyphenyl)sulfone, 4,4′-bis(4-aminophenoxy)diphenyl, 1,4-bis(4-aminophenoxy)benzene, and 2,2-bis(4-aminophenoxyphenyl)hexafluoropropane.

As A, further, the following compounds can be also used: compounds having a carboxyl group or an amino group such as 4-(3-hydroxyphenoxycarbonyl)-1,3-diaminobenzene, 4-(2-hydroxyphenoxycarbonyl)-1,3-diaminobenzene, 4-(3-hydroxyphenoxycarbonyl)-1,3-diaminobenzene, 4-(4-hydroxyphenoxycarbonyl)-1,3-diaminobenzene, 5-(2-hydroxyphenoxycarbonyl)-1,3-diaminobenzene, 5-(3-hydroxyphenoxycarbonyl)-1,3-diaminobenzene, 5-(4-hydroxyphenoxycarbonyl)-1,3-diaminobenzene, 4-(2-aminophenoxy)-1,3-diaminobenzene, 4-(3-aminophenoxy)-1,3-diaminobenzene, 4-(4-aminophenoxy)-1,3-diaminobenzene, 5-(2-aminophenoxy)-1,3-diaminobenzene, 5-(3-aminophenoxy)-1,3-diaminobenzene, 5-(4-aminophenoxy)-1,3-diaminobenzene, 4-(3,5-aminophenoxy)-1,3-diaminobenzene, and 4-(2-aminophenoxycarbonyl)-1,3-diaminobenzene.

The repeating unit containing B1 in the formula (s1-1) is a repeating unit containing an alkenyl group having an unsaturated double bond at a terminal thereof as the crosslinking site. B1 is a group represented by the following formula (b1).

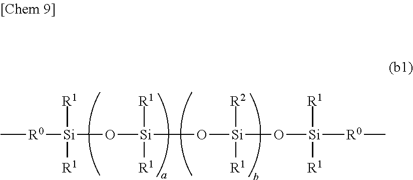

In the formula (b1), R⁰ is a single bond, a divalent hydrocarbon group having 1 to 4 carbon atoms or a phenylene group, and is preferably an alkylene group or a phenylene group, and is more preferably an alkylene group having 3 to 4 carbon atoms or a phenylene group. The fact that R⁰ is a single bond means that N and Si are directly bonded to each other in the formula (1). The meaning of the single bond in the other compound in the present specification has the same meaning.

In the formula (b1), R¹'s are each independently a monovalent hydrocarbon group having 1 to 8 carbon atoms and examples thereof include alkyl groups such as methyl group, ethyl group, propyl group, butyl group, pentyl group, and hexyl group; cycloalkyl groups such as cyclopentyl group and cyclohexyl group; aryl groups such as phenyl group; and aralkyl groups such as benzyl group and phenethyl group. From the standpoint of the easiness of availability of raw materials, methyl group, ethyl group and phenyl group are preferred for R′.

In the formula (b1), R² represents an alkenyl group having an unsaturated double bond at a terminal thereof and is preferably an alkenyl group having 2 to 6 carbon atoms, particularly preferably vinyl group or an alkenyl group having a vinyl group at a terminal thereof and having 3 to 6 carbon atoms, and especially preferably vinyl group. The ranging manner of the siloxane chain in the formula (b2) may be ranged block-wise or ranged randomly. A block-wise ranging moiety may be included in a randomly ranging moiety. In the similar representation in the other formula, the meanings of ranging of the repeating units are also the same. The bonding position of R² in the siloxane chain of the polyimide silicone may be any part such as an end part or a central part.

In the formula (b1), a is an integer of from 0 to 100 and preferably an integer of from 3 to 70 and b is an integer of from 1 to 100, preferably an integer of from 3 to 70, and more preferably an integer of from 5 to 50.

In the case where B1 is the formula (b1), the repeating unit containing B1 can be obtained through a reaction of a tetracarboxylic acid anhydride having the X group with a diaminosiloxane having amino groups at both terminal thereof and having an alkenyl group having an unsaturated double bond at a terminal thereof in the silicone moiety.

The tetracarboxylic acid anhydride having the X group includes the following compounds:

tetracarboxylic acid anhydrides having at least two aromatic rings, such as 3,3′,4,4′-diphenyltetracarboxylic acid dianhydride, 3,3′,4,4′-benzophenonetetracarboxylic acid dianhydride, 3,3′,4,4′-diphenylether tetracarboxylic acid dianhydride, 3,3′,4,4′-diphenylsulfone tetracarboxylic acid dianhydride, 2,2-bis(3,3′,4,4′-tetracarboxyphenyl)tetrafluoropropane dianhydride, 2,2-bis(3,3′,4,4′-tetracarboxyphenyl)hexafluoropropane dianhydride, 2,3,3′,4′-biphenyltetracarboxylic acid dianhydride, 2,3,3′,4′-benzophenone tetracarboxylic acid dianhydride, 2,3,3′,4′-diphenylether tetracarboxylic acid dianhydride, 2,3,3′,4′-diphenylsulfone tetracarboxylic acid dianhydride, 2,2-bis(3,4-dicarboxyphenoxyphenyl)propane dianhydride, and 2,2′-bis(3,4-dicarboxyphenoxyphenyl)sulfone dianhydride;
tetracarboxylic acid anhydrides such as pyromellitic acid anhydride, 1,4,5,8-naphthalene
tetracarboxylic acid anhydride, and 2,3,6,7-naphthalene tetracarboxylic acid anhydride.

As the diaminosiloxane having, in the silicone moiety, an alkenyl group having an unsaturated double bond at a terminal thereof, there may be mentioned compounds which has —(CH₂)ₙNH₂ groups at both terminals of a dimethylsiloxane chain and a part of the methyl groups are replaced with an alkenyl group (preferably vinyl group) having an unsaturated double bond at a terminal thereof, and preferred is a compound represented by the formula (s2-10) to be mentioned below.

The polyimide silicone (S1) can be synthesized by reacting the diamine compound, the diaminosiloxane having an alkenyl group having an unsaturated double bond at a terminal thereof in the silicone moiety, and the tetracarboxylic acid anhydride having the X group.

With regard to the polyimide silicone of the formula (s1-1), the weight-average molecular weight thereof in terms of polystyrene is preferably from 5,000 to 150,000 and particularly preferably from 8,000 to 100,000. When the molecular weight is 5,000 or more, strength of the resulting resin layer is good. On the other hand, when the molecular weight is 150,000 or less, handling is good since compatibility with a solvent is good. The polyimide silicone can be produced by known methods.

The resin composition containing the polyimide silicone (S1) may further contain a peroxide that forms a radical upon heating up to the first temperature (T1>room temperature).

In the case of containing the peroxide, since the crosslinking reaction between the R² groups proceeds to some extent in the presence of a radical formed from the peroxide, initial hardness of the resin layer increases. It is possible to adjust the initial hardness of the resin layer by the number of R², the amount of the peroxide, and the like. In the case where it is desired to decrease the initial hardness of the resin layer, it is preferred to set the amount of the peroxide so that the alkenyl group (vinyl group) remains after heating at the first temperature. The radical formed from the peroxide is incorporated into the molecule of the polyimide silicone, there is an advantage that no gas generates.

Specific examples of the peroxide include the following examples.

There may be mentioned peroxy carbonate such as t-butylperoxy(2-ethylhexyl) carbonate (temperature of a half-life of ten hours: 100° C., trade name: LUPEROX TBEC, manufactured by ARKEMA Yoshitomi, Ltd.), t-almyperoxy(2-ethylhexyl) carbonate (temperature of a half-life of ten hours: 99° C., trade name: LUPEROX TAEC, manufactured by ARKEMA Yoshitomi, Ltd.), 1,6-bis(t-butylperoxycarbonyloxy)hexane (temperature of a half-life of ten hours: 97° C., temperature of a half-life of one hour: 115° C., trade name: KAYALENE 6-70, manufactured by Kayaku Akzo Co., Ltd.), and bis(4-t-butylcyclohexyl)peroxy dicarbonate (trade name PERKADOX 16, manufactured by Kayaku Akzo Co., Ltd.), which are peroxides for low-temperature curing having a temperature of a half-life of ten hours of around 100° C.

There may be used dicumyl peroxide (temperature of a half-life of ten hours: 116.4° C., temperature of a half-life of one hour: 135.7° C.), di-tert-hexyl peroxide (temperature of a half-life of ten hours: 116.4° C., temperature of a half-life of one hour: 136.2° C.), 2,5-dimethyl-2,5-di(t-butylperoxy)hexane (temperature of a half-life of ten hours: 117.9° C., temperature of a half-life of one hour: 138.1° C.), di-tert-butyl peroxide (temperature of a half-life of ten hours: 123.7° C., temperature of a half-life of one hour: 144.1° C.), and 2,5-dimethyl-2,5-di(t-butylperoxy)hexyne-3 (PERHEXYNE 25B manufactured by NOF Corporation, temperature of a half-life of ten hours: 128.4° C., temperature of a half-life of one hour: 149.9° C.), which are peroxides for medium-temperature curing having a temperature of a half-life of ten hours of around 110 to 130° C.

There may be also used diisopropylbenzene hydroperoxide (temperature of a half-life of ten hours: 145.1° C., temperature of a half-life of one hour: 172.8° C.), t-butyl hydroperoxide (temperature of a half-life of ten hours: 166.5° C., temperature of a half-life of one hour: 196.3° C.), and 2,3-dimethyl-2,3-diphenylbutane (temperature of a half-life of ten hours: 210° C., temperature of a half-life of one hour: 234° C.), which are peroxides for high-temperature curing having a temperature of a half-life of ten hours of around 140 to 210° C. These peroxides may be used singly or in combination.

As the peroxide, for the purpose of generating a sufficient amount of radical upon heating up to the first temperature, those having a temperature of a half-life of one hour lower than the first temperature are suitable.

Particularly, in the case where the polyimide silicone (S1) is crosslinked upon crosslinking by heating at the first temperature, it is preferred to use, for example, a peroxy carbonate as the peroxide.

As the peroxy carbonate, besides those mentioned above, there may be mentioned monoperoxy carbonates such as t-butylperoxy(isopropyl) carbonate, t-butylperoxy(2-ethylhexyl) carbonate, and t-amylperoxy(2-ethylhexyl) carbonate; di(2-ethylhexyl)peroxy dicarbonate, 1,6-bis(t-butylperoxycarbonyloxy)hexane, bis(4-t-butylcyclohexyl)peroxy dicarbonate, di(2-ethoxyethyl)peroxy dicarbonate, di(n-propyl)peroxy dicarbonate, diisopropylperoxy dicarbonate, and the like. Of these, t-butylperoxy(2-ethylhexyl) carbonate, t-amylperoxy(2-ethylhexyl) carbonate, 1,6-bis(t-butylperoxycarbonyloxy) hexane, and bis(4-t-butylcyclohexyl)peroxy dicarbonate are preferred. These peroxy carbonates are particularly preferred since they have good compatibility with a polyimide silicone and achieve rapid curing at low temperature.

The peroxide is preferably used in an amount of from 1 to 10 molar equivalents and particularly preferably used in an amount of from 2 to 7 molar equivalents to the number of moles of the alkenyl group having an unsaturated double bond at a terminal thereof, in the silicone moiety represented by the above (b1). When the amount is 1 molar equivalent or more, solvent resistance of the resin layer is good. When the amount is 10 molar equivalents or less, storage stability of the resin composition and high-temperature and humidity resistance of the resin layer are good.

The first temperature in the polyimide silicone (S1) is preferably from 90 to 210° C. and particularly preferably from 100 to 180° C. The second temperature is preferably a temperature of +10 to +50° C. higher than the first temperature and particularly preferably a temperature of +20 to +30° C. higher than the first temperature.

[Polyimide Silicone (S2) in which B is (B2) Having an Alkoxysilyl Group]

The polyimide silicone (S2) has a repeating unit in which B is a silicone moiety (B2) having an alkoxysilyl group in the above formula (1). The repeating unit is represented by the following formula (s2) and (B2) is represented by the following formula (b2).

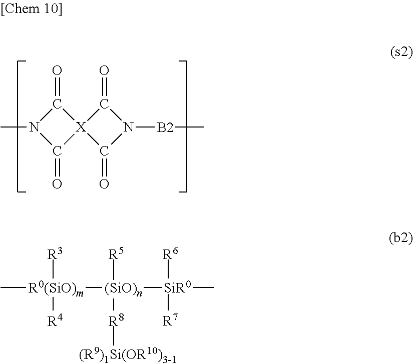

In the formula (s2), X has the same meaning as the meaning in the formula (s1).

However, in the formula (b2), the meanings of R⁰, R³ to R¹⁰, m, n, and l have the same meanings as the meanings in the formula (s2-1) to be mentioned below.

The polyimide silicone (S2) is preferably composed of two kinds of repeating units of a repeating unit represented by the formula (s2-1) that is a repeating unit of the silicone moiety having an alkoxysilyl group and a repeating unit represented by the formula (s2-2) that is another repeating unit.

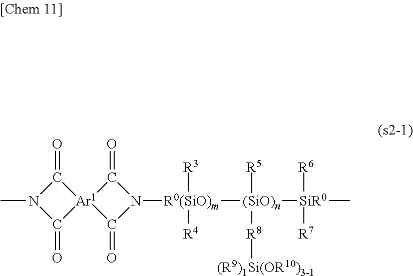

In the formula (s2-1), Ar¹ represents a tetravalent organic group and R⁰ represents a single bond, a divalent hydrocarbon group having 1 to 4 carbon atoms or a phenylene group. R⁰ is preferably an alkylene group or a phenylene group, and more preferably an alkylene group having 3 or 4 carbon atoms or a phenylene group. R³ to R⁷, R⁹, and R¹⁰ represent a hydrocarbon group having 1 to 6 carbon atoms and R⁸ is a linear or branched alkylene group having 2 to 6 carbon atoms and, in the case where the carbon number is 2, ethylene group is preferred. m and n each independently represents an integer of from 1 to 10 and 1 represents an integer of from 0 to 2. R³ to R⁷, R⁹, and R¹⁰ are preferably an alkyl group having 1 to 3 carbon atoms and particularly preferably methyl group.

A preferred embodiment of Ar¹ in the formula (s2-1) is the same as X in the formula (s1-1).

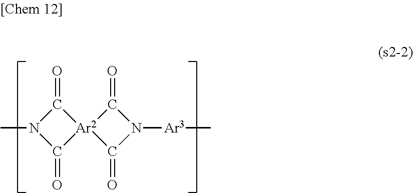

The repeating unit represented by the formula (s2-2) is a repeating unit containing no crosslinking site in the polyimide silicone (S2). In the formula (s2-2), Ar² represents a tetravalent organic group and a preferred embodiment of Ar² is the same as X in the formula (s1-1). Ar³ represents a divalent organic group having two or more aromatic rings. As Ar³ in the formula (s2-2), the same group as the formula (a1) in the polyimide silicone (S1) may be mentioned and specific examples are also the same.

The polyimide silicone (S2) preferably contains from 1 to 80% by mol of the repeating unit represented by the formula (s2-1) and from 20 to 99% by mol of the repeating unit represented by the formula (s2-2) and particularly preferably contains from 10 to 60% by mol of the repeating unit represented by the formula (s2-1) and from 40 to 90% by mol of the repeating unit represented by the formula (s2-2).

The repeating unit represented by the formula (s2-1) can be obtained through a reaction of a tetracarboxylic acid anhydride having Ar¹ with a diaminosiloxane having amino groups at both terminals thereof and having an alkoxysilyl group in a silicone moiety thereof.

The repeating unit represented by the formula (s2-2) can be obtained through a reaction of a diamine compound having two or more aromatic rings (Ar³) and two amino groups with a tetracarboxylic acid compound having the Ar² group. As the diamine compound, use can be made of the same compound as the diamine used for the synthesis of the repeating unit of the formula (s1-1) in the case where A is the formula (a1).

As the tetracarboxylic acid anhydride that forms the repeating unit represented by the formula (s2-1) and the repeating unit represented by the formula (s2-2), the same compounds as the tetracarboxylic acid anhydrides having the X group, which are used for obtaining the repeating unit represented by the formula (1), can be exemplified.

In the case where B2 is the formula (b2), the repeating unit containing B2 can be obtained through a reaction of the tetracarboxylic acid anhydride having the X group with the diaminosiloxane having amino groups at both terminals thereof and having an alkoxysilyl group in a silicone moiety thereof.

The diaminosiloxane that forms the repeating unit represented by the formula (s2-1) is preferably a compound in which an alkoxysilyl group is bonded to the silicone moiety thereof. The compound includes compounds represented by the following formulae (s2-A) to (s2-J). The compounds represented by the formulae (s2-A) to (s2-J) can be used singly or in combination of more of them.

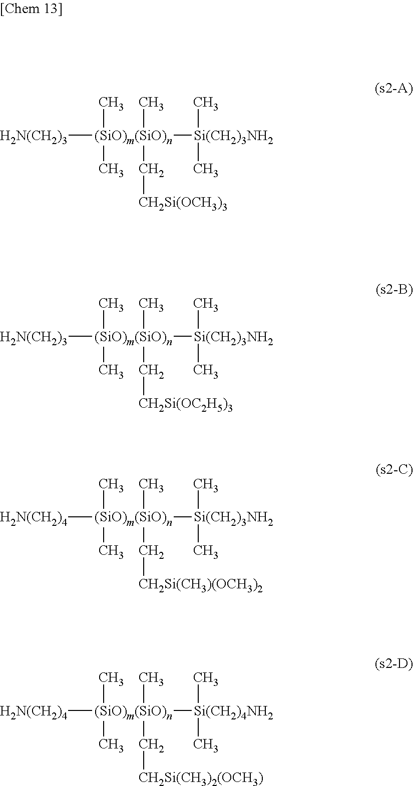

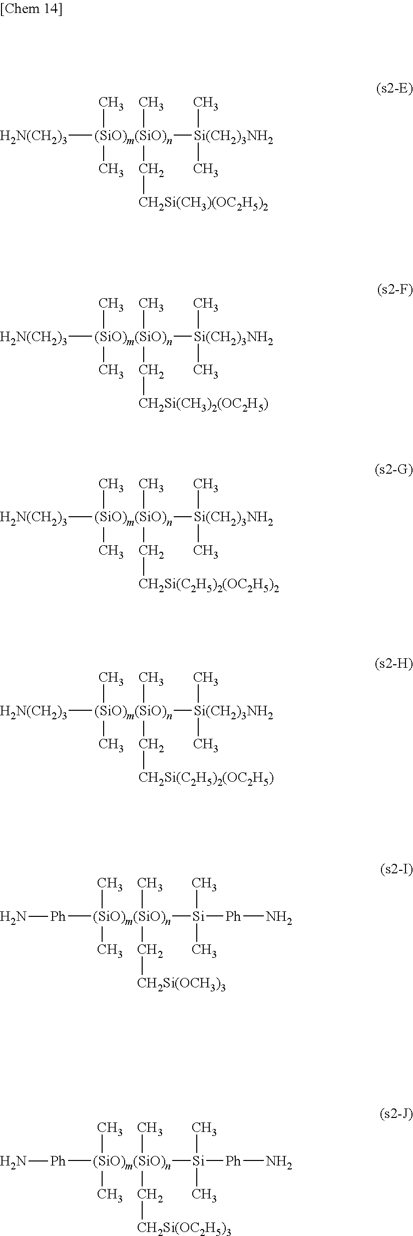

In the formulae (s2-A) to (s2-J), m and n each independently represents an integer of from 1 to 10. Ph represents a 1,4-phenylene group and the same shall apply hereinafter.

As the other producing process of the compound having the repeating unit represented by the formula (s2-1), there may be mentioned a process of reacting a vinyl group-containing diaminosiloxane represented by the following formula (s2-10) with a tetracarboxylic acid dianhydride to compose a repeating unit represented by the following formula (s2-11) and subsequently subjecting a compound represented by the following formula (s2-12) that is a compound having an alkoxysilyl group to a hydrosilylation reaction therewith to introduce the alkoxysilyl group.

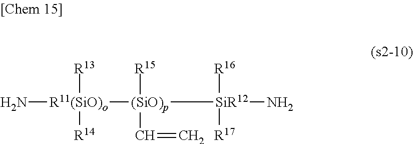

In the formula (s2-10), R¹¹ and R¹² represent a single bond, an alkylene group having 1 to 4 carbon atoms or a phenylene group, R¹³ to R¹⁷ represent a hydrocarbon group having 1 to 6 carbon atoms, and o and p each independently represents an integer of from 1 to 10.

R¹¹ and R¹² are preferably an alkylene group having 3 or 4 carbon atoms or a phenylene group.

R¹³ to R¹⁷ are preferably an alkyl group having 1 to 3 carbon atoms, and particularly preferably methyl group.

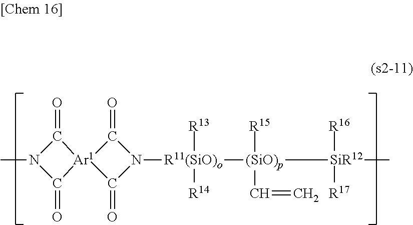

In the formula (s2-11), Ar¹ is the same as the description in the above formula (s2-1) including the preferred embodiment and R¹¹, R¹², R¹³ to R¹⁷, o, and p are each the same as the description in the above formula (s2-10) including the preferred embodiment.

[Chem 17]

(R²¹O)₃₋ₓSiH(R²²)ₓ (s2-12)

In the formula (s2-12), R²¹ and R²² represent a hydrocarbon group having 1 to 6 carbon atoms or a hydrocarbon group having an ether bond, and x represents an integer of from 0 to 2. Owing to high reactivity, R²¹ and R²² are preferably a hydrocarbon group having 1 to 3 carbon atoms from this viewpoint.

For example, the following examples may be mentioned as the vinyl group-containing diaminosiloxane represented by the formula (s2-10).

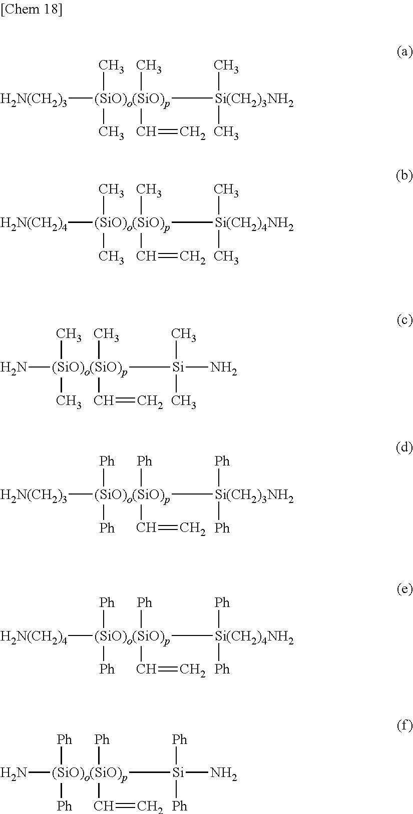

In the formulae (a) to (f), o and p are the same as o and p in the formula (s2-10), respectively.

Examples of the hydroalkyl silicate compound represented by the formula (s2-12) include the following ones.

[Chem 19]

HSKOCH₃)₃ (s2-12a)

HSKOC₂H₅)₃ (s2-12b)

HSi(CH₃)(OCH₃)₂ (s2-12c)

HSi(CH₃)(OC₂H₅)₂ (s2-12d)

HSi(CH₃)₂(OCH₃) (s2-12e)

HSi(CH₃)₂(OC₂H₅) (s2-12f)

HSi(C₂H₅)(OCH₃)₂ (s2-12g)

HSi(C₂H₅)₂(OCH₃) (s2-12h)

HSi(C₂H₅)(OC₂H₅)₂ (s2-12i)

HSi(C₂H₅)₂(OC₂H₅)₂ (s2-12j)

HSKOCH₂CH₂OCH₃)₃ (s2-12k)

HSi(OCH₂CH₂OC₂H₅)₃ (s2-12m)

Moreover, at the time when the hydroalkyl silicate and the repeating unit represented by the formula (s2-11) are subjected to a hydrosilylation reaction to compose the repeating unit represented by the above formula (s2-1), chloroplatinic acid or the like can be used as a reaction catalyst. At the time of the reaction with the vinyl group of the repeating unit represented by the formula (s2-11), the hydroalkyl silicate compound is preferably used in the range of from 1.0 to 5.0 molar equivalents to the number of moles of the vinyl group.

Furthermore, as a synthetic process of the polyimide silicone (S2), it can be obtained by reacting a tetracarboxylic acid anhydride having the X group, a diamine compound having two or more aromatic rings (Ar³) and two amino groups, and a diaminosiloxane having amino groups at both terminals thereof and an alkoxysilyl group in a silicone moiety thereof by a known method.

As another process, it can be obtained by reacting a tetracarboxylic acid anhydride, a diamine compound having two or more aromatic rings (Ar³) and two amino groups, and a diaminosiloxane having amino groups at both terminals thereof and vinyl group in a silicone moiety thereof by a known method, followed by hydrosilylation of a compound having an alkoxysilyl group to the vinyl group of the resulting compound.

The thus synthesized polyimide silicone (S2) is excellent in adhesion performance since it contains a silicate group at side chains thereof, and also becomes a material excellent in heat resistance, strength, and solvent resistance since it can provide a crosslinked structure by a hydrolysis reaction or a heat hydrolysis reaction. Since the polyimide silicone (S2) is crosslinked by heating at high temperature (second temperature or higher), there is also an advantage that a peroxide may not be incorporated into the resin composition.

The first temperature in the polyimide silicone (S2) is preferably from 90 to 180° C. and particularly preferably from 90 to 160° C. The second temperature is preferably from 180 to 300° C. and particularly preferably from 200 to 280° C.

[Polyimide silicone (S3) in which B is group (B3) having an alkyl group]

The polyimide silicone (S3) has a repeating unit having a group (B3) having an alkyl group directly bonded to a silicon atom of the silicone moiety, and the repeating unit is represented by the formula (s3). The polyimide silicone (S3) is preferably a compound having a repeating unit represented by the formula (s3) and a repeating unit represented by the following formula (s3-2). The group (B3) in the formula (s3) is represented by the formula (b3).

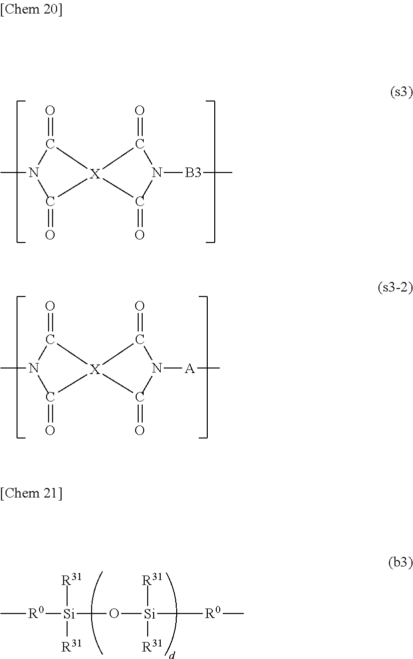

In the formula (s3), X is the same as in the formula (s1) including the preferred embodiment. X and A in the formula (s3-2) have the same meanings as the meanings in the formula (s1-1). In the formula (b3), R⁰ represents a single bond, a divalent hydrocarbon group having 1 to 4 carbon atoms, or a phenylene group. R⁰ is preferably an alkylene group or a phenylene group, and more preferably an alkylene group having 3 to 4 carbon atoms or a phenylene group. R³¹ is a hydrocarbon group having 1 to 6 carbon atoms. d represents an integer of from 1 to 200, preferably an integer of from 3 to 140, and more preferably an integer of from 5 to 100.

With regard to the polyimide silicone having the repeating unit represented by the formula (s3), the weight-average molecular weight thereof in terms of polystyrene is from 5,000 to 150,000 and preferably from 8,000 to 100,000. When the molecular weight is 5,000 or more, strength of the resulting film of the polyimide silicone is good. On the other hand, when the molecular weight is 100,000 or less, compatibility with a solvent is good and handling is easy. The polyimide silicone (S3) can be obtained by a similar process to the producing process of the repeating unit in the case where A is the formula (a1) in the producing process of the polyimide silicone (S1), that is, through a reaction of the diamine compound having two or more aromatic rings and two amino groups, the tetracarboxylic acid anhydride having the X group, and the diaminosiloxane having amino groups at both terminals thereof and having no functional group other than the above crosslinking point in a silicone moiety thereof. As the diaminosiloxane having amino groups at both terminals thereof and having no functional group other than the above crosslinking point in a silicone moiety thereof, a compound represented by the formula (g) may be mentioned.

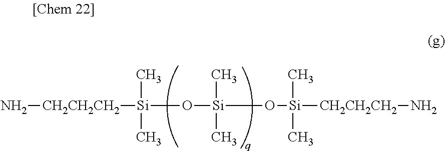

In the formula (g), q is an integer of from 1 to 100.

The alkyl group directly bonded to a silicon atom in the silicone moiety undergoes a crosslinking reaction by a radical generated from a peroxide or the like. For example, as the peroxide, in order to suppress the generation of radical upon heating up to the first temperature, one having a temperature of a half-life of ten hours higher than the first temperature is suitable. Thereby, the initial hardness of the resin layer is prevented from becoming exceedingly high.

In addition, as the peroxide, in order to form a sufficient amount of radical upon heating up to the third temperature (T3>T1), one having a temperature of a half-life of one hour lower than the third temperature is suitable. Thereby, the hardness of the resin layer after heating at the third temperature can be optimized. The hardness after heating is decided by the amount of the peroxide to be added and the like. The amount of the peroxide to be added is preferably an equivalent value of 10 to 50% relative to the molar equivalent of the alkyl group directly bonded to a silicon atom of the silicone moiety.

As the peroxide that can be added to the polyimide silicone (S3), one having the above temperature range is usable but, from the standpoints of the easiness of drying a solvent and storage stability, one having a temperature of a half-life of ten hours of from about 100 to 130° C. is preferred. Those having a temperature of a half-life of ten hours within this range include low-temperature decomposable peroxides and medium-temperature decomposable peroxides mentioned above may be mentioned.

When the crosslinking site is an alkyl group directly bonded to a silicon atom, since the producing steps of the polyimide silicone resin are small in number, the case is preferred due to low costs as compared with the types of S1 and S2.

The first temperature in the polyimide silicone (S3) is preferably from 110 to 210° C. and particularly preferably from 110 to 180° C. The second temperature is preferably a temperature of +10 to +50° C. higher than the first temperature and particularly preferably a temperature of +20 to +30° C. higher than that.

The resin composition of the present invention contains the polyimide silicone, the solvent, and the peroxide that may be optionally added depending on the crosslinking site and the crosslinking conditions. The composition preferably consists of the above components alone but may contain other components according to need.

### (Crosslinking of Polyimide Silicone)

As a method of crosslinking the polyimide silicone of the present invention, first, the solvent is vaporized from the resin composition by heating at the first temperature.

Then, the polyimide silicone of the present invention is crosslinked by heating to the second temperature. The degree of crosslinking can be adjusted so that the interaction with a substrate to be attached later does not become exceedingly high. Also, by selecting the crosslinking site, it is possible to achieve crosslinking by any method at any temperature. The crosslinking method can be also selected depending on the heat-resistant temperature of the substrate.

### (Uses of Resin Composition)

The resin composition of the present invention can be used for a resin layer of a laminate for an electronic device. By using the polyimide silicone of the present invention, there can be obtained a laminate which has such a degree of a close adhesive force that peeling from the fixing plate is less prone to occur and positional shifting from the substrate is less prone to occur at ordinary temperature and is easily peeled off from the substrate after the heating step.

### (Laminate and Structure)

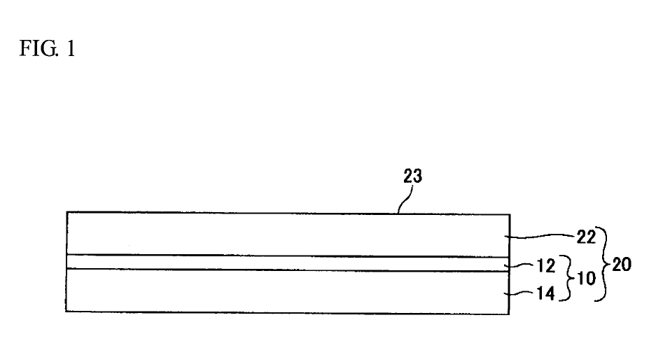

In the present invention, the laminate 10 has a resin layer 12 capable of being attached to a substrate 22 and a fixing plate 14 that fixes the resin layer 12, as shown in FIG. 1. Moreover, one having a substrate provided on the surface of the resin layer of the laminate is called a structure.

The structure 20 has the above laminate 10 and the substrate 22 supported by the resin layer 12 of the laminate 10. The laminate 20 may have substantially the same thickness as that of a conventional substrate, in order to manufacture an electronic device by using processing facilities which process a conventional substrate (a substrate that is not reinforced with a laminate). The following will describe individual components based on FIG. 1.

### (Substrate)

The substrate 22 is a substrate for an electronic device. On a surface 23 that is opposite to the resin layer 12 of the substrate 22, at least a part (for example, a thin-film transistor, etc.) of constituent members constituting an electronic device is formed in the step of producing the electronic device.

As a material of the substrate 22, use can be made of, for example, a ceramic, a resin, a metal, and a semiconductor. Of these, a resin is preferred. The material of the substrate 22 is appropriately selected depending on the kind of the electronic device. For example, in the case where a flexible substrate is used as a liquid crystal panel (LCD) or an organic EL panel (OLED), a resin film is used. Specific examples of the resin film include, as crystalline resins, films of polyamide, polyacetal, polybutylene terephthalate, polyethylene terephthalate, polyethylene naphthalate, syndiotactic polystyrene, and the like that are thermoplastic resins and, as thermosetting resins, polyphenylene sulfide, polyether ether ketone, liquid crystal polymers, fluorinated resins, polyether nitrile, and the like.

Moreover, as non-crystalline resins, there may be mentioned films of polycarbonate, modified polyphenylene ether, polycyclohexene, polynorbornene-based resins, and the like that are thermoplastic resins and, as thermosetting resins, polysulfone, polyether sulfone, polyarylate, polyamideimide, polyetherimide, thermoplastic polyimide, and the like. Particularly, non-crystalline and thermoplastic resin films are preferred.

The thickness of the substrate 22 is not particularly limited but is preferably 0.7 mm or less, more preferably 0.3 mm or less, and further preferably 0.1 mm or less for the purpose of weight saving and thinning of the electronic device.

### (Fixing Plate)

The fixing plate 14 has a function of supporting the substrate 22 to reinforce it through the resin layer 12 to be mentioned below. The fixing plate 14 prevents deformation, scratching, damage, and the like of the substrate 22 in the producing steps of an electronic device.

The material of the fixing plate 14 is, for example, glass, a ceramic, a resin, a semiconductor, a metal, a glass/resin composite, or the like. The material of the fixing plate 14 is selected depending on the kind of the electronic device and the material of the substrate 22. When the material is the same kind as that of the substrate 22, generation of warp upon heating can be suppressed since a difference in thermal expansion between the fixing plate 14 and the substrate 22 is small.

The difference (absolute value) in average linear expansion coefficient between the fixing plate 14 and the substrate 22 is appropriately set depending on the surface size of the substrate 22 and, for example, is preferably 35×10⁻⁷/° C. or less. Here, the term “average linear expansion coefficient” means an average linear expansion coefficient (JIS R 3102-1995) in a temperature range of from 50 to 300° C.

The thickness of the fixing plate 14 is not particularly limited and is preferably 0.7 mm or less for adopting the structure 20 to existing processing facilities. Moreover, the thickness of the fixing plate 14 is preferably 0.4 mm or more for enforcing the substrate 22. The fixing plate 14 may be thicker or thinner than the substrate 22.

### (Resin Layer)

When the resin layer 12 is closely adhered to the substrate 22, positional shifting of the substrate 22 is prevented until a peeling operation is performed. Moreover, the resin layer 12 is easily peeled off from the substrate 22 by the peeling operation. Since the peeling can be conducted easily, the substrate 22 can be prevented from damaging and peeling at an unintended position can be also prevented.

The resin layer 12 is formed so that the bonding force to the fixing plate 14 becomes relatively higher than the bonding force to the substrate 22 (details of the forming method will be mentioned below). Thereby, at the time of performing the peeling operation, the structure 20 can be prevented from peeling at an unintended position.

The resin layer 12 is formed by heating the above resin composition at the first temperature and drying it. The resin layer 12 may be formed by application on the fixing plate 14 and drying or may be formed by application on a given substrate and drying and subsequently peeling off from the given substrate.

Since the crosslinking reaction of the crosslinkable moiety in the silicone moiety contained in the polyimide silicone does not sufficiently proceed at the first temperature or lower, a resin layer 12 excellent in flexibility that is a characteristic of a silicone can be obtained and thus a resin layer 12 excellent in adhesive property can be obtained. Accordingly, when being closely adhered to the substrate 22, the resin layer 12 can prevent the positional shifting of the substrate 22 until the peeling operation is performed.

When the layer is heated to the third temperature exceeding the first temperature, the crosslinking reaction of the silicone moiety proceeds at the second temperature in the middle thereof, and thus thermal decomposition of the silicone moiety is suppressed to inhibit the generation of low molecular gases (e.g., cyclic siloxane). Accordingly, the resin layer becomes a layer excellent in heat resistance, particularly, becomes a layer excellent in heat resistance even against heating to the third temperature or higher.

Also, when the crosslinking reaction of the silicone moiety proceeds as a result of heating up to the third temperature, since the resin layer 12 is further cured to increase an elastic modulus and decrease adhesive property, the resin layer 12 excellent in detachability after heating can be obtained. By decreasing the adhesive property, the peeling can be inhibited from becoming difficult due to the interaction between the resin layer 12 and the substrate 22 upon heating.

The initial peel strength between the resin layer 12 and the substrate 22 depends on the producing steps of an electronic device but, for example, in the case of using a polyimide film having a plate thickness of 0.05 mm (KAPTON 200HV manufactured by Du Pont-Toray Co., Ltd.) as the substrate 22, the strength is, for example, 0.3 N/25 mm or more, preferably 0.5 N/25 mm or more, and more preferably 1 N/25 mm or more at 90° peeling test (in accordance with JIS Z0237). Here, the “initial peel strength” means a peel strength between the resin layer 12 and the substrate 22 immediately after the manufacture of the structure 20 and is a peel strength measured at room temperature before the resin layer 12 is heated at the third temperature.

When the initial peel strength is 0.3 N/25 mm or more, unintended separation can be sufficiently restricted. On the other hand, when the initial peel strength exceeds 5 N/25 mm, for example, in the case of correcting the positional relation between the resin layer 12 and the substrate 22, it becomes difficult to peel off the resin layer 12 from the substrate 22.

The peel strength between the resin layer 12 and the substrate 22 after heating depends on the producing steps of an electronic device but is, for example, preferably 8.5 N/25 mm or less, more preferably 7.8 N/25 mm or less, and 4.5 N/25 mm or less at 90° peeling test. Here, the “peel strength after heating” means a peel strength between the resin layer 12 and the substrate 22 measured at room temperature after the resin layer 12 is heated at the third temperature.

When the peel strength after heating is 0.3 N/25 mm or more, unintended separation can be sufficiently restricted. On the other hand, when the peel strength after heating exceeds 10 N/25 mm, it becomes difficult to peel off the resin layer 12 from the substrate 22.

The thickness of the resin layer 12 is not particularly limited and is preferably from 1 to 50 μm, more preferably from 5 to 30 μm, and further preferably from 7 to 20 μm. By controlling the thickness of the resin layer 12 to 1 μm or more, the deformation of the substrate 22 can be suppressed in the case where bubbles or foreign particles are entrained between the resin layer 12 and the substrate 22. On the other hand, when the thickness of the resin layer 12 exceeds 50 μm, time and materials are required for the formation of the resin layer 12, so that the case is not economical.

### (Producing Process of Laminate)

As processes for producing the laminate 10, there are processes such as (1) a process of applying a resin composition on the fixing plate 14 and heating it at the first temperature and drying it, to form the resin layer 12; and (2) a process of press-bonding a resin layer (the resin layer is preferably a resin layer having adhesive property), which has been formed beforehand by heating the resin composition at the first temperature and drying it, onto the fixing plate 14.

In the above process of (1), since the resin composition interacts with the fixing plate 14 at the time of forming the resin layer 12, the bonding force between the fixing plate 14 and the resin layer 12 can be made higher than the bonding force between the resin layer 12 and the substrate 22.

Examples of the applying method of the resin composition include a spray coating method, a die coating method, a spin coating method, a dip coating method, a roll coating method, a bar coating method, a screen printing method, and a gravure coating method. These coating methods are appropriately selected depending on the kind of the resin composition.

The drying conditions (the first temperature and holding time thereof) of the resin composition are appropriately selected, for example, depending on the kind of the polyimide silicone and the solvent.

The above process of (2) is effective in the case where the adhesive property of the resin layer is low toward the substrate 22 and is high toward the fixing plate 14. Before the contact with the resin layer, a difference in the adhesive property toward the resin layer may be provided by subjecting the surface of the substrate 22 or the fixing plate 14 to a surface treatment.

The press-bonding is desirably carried out under an environment of high cleanliness. Methods for the press-bonding include a roll method, a press method, and the like. The atmosphere for carrying out the press-bonding may be an atmospheric pressure atmosphere but, for suppressing the mixing of bubbles, it is preferably a reduced pressure atmosphere. The temperature for carrying out the press-bonding is sufficiently a temperature lower than the second temperature and, for example, may be room temperature.

### (Producing Process of Structure)

As processes for producing the structure 20, there are processes such as (1) a process of forming the resin layer 12 by applying a resin composition on the fixing plate 14, heating it at the first temperature and drying it, and subsequently press-bonding the substrate 22 on the resin layer 12; (2) a process of press-bonding a resin film, which has been formed beforehand by heating the resin composition at the first temperature and drying it, with sandwiching it between the substrate 22 and the fixing plate 14; and (3) a process of forming the resin layer 12 by sandwiching a resin composition between the substrate 22 and the fixing plate 14, heating it at the first temperature and drying it. Incidentally, since the press-bonding conditions in the above processes of (1) and (2) are substantially the same as the press-bonding conditions in the process for producing the laminate 10, explanation thereof is omitted.

In the above process of (1), the resin composition interacts with the fixing plate 14 at the time of forming the resin layer 12. Therefore, the bonding force between the fixing plate 14 and the resin layer 12 can be made higher than the bonding force between the resin layer 12 and the substrate 22.

The above process of (2) is effective in the case where the adhesive property of the resin layer is low toward the substrate 22 and is high toward the fixing plate 14. Before the contact with the resin layer, a difference in the adhesive property toward the resin layer may be provided by subjecting the surface of the substrate 22 or the fixing plate 14 to a surface treatment.

The above process of (3) is effective in the case where the adhesive property of the resin composition upon drying is low toward the substrate 22 and is high toward the fixing plate 14. Before the contact with the resin composition, a difference in the adhesive property of the resin composition upon drying may be provided by subjecting the surface of the substrate 22 or the surface of the fixing plate 14 to a surface treatment.

### (Uses of Structure)

The substrate in the structure of the present invention is used with being reinforced with the laminate of the present invention and can be used for producing various products having the substrate as a part of the product structure. As the products, there may be mentioned electronic devices such as an organic EL panel and a solar cell.

The substrate may be a base material itself composed of a specific material or a substrate having functional layer(s) according to purpose(s) on the base material. As a producing process using the substrate having functional layer(s), a process for producing an electronic device may be mentioned.

### (Producing Process of Electronic Device)

The process for producing an electronic device comprises a forming step of forming at least a part of functional members of the electronic device on the substrate 22 of the structure 20 and a removing step of removing the resin layer 12 and the fixing plate 14 by peeling off the resin layer 12 from the substrate 22. In the case where only a part of constituent members is formed, the remaining constituent members may be formed on the substrate 22 after the removing step.

The step of forming the constituent members of an electronic device is selected depending on the kind of the electronic device. The step of forming a liquid crystal panel (LCD) include, for example, a step of forming TFT (thin-film transistor) or the like on a substrate to manufacture a TFT substrate, a step of forming CF (color filter) or the like on a substrate to manufacture a CF substrate, a step of encapsulating a liquid crystal material between the TFT substrate and the CF substrate to manufacture a panel, and the like step. In this case, the removing step is conducted, for example, after the step of producing the panel or between the step of producing the TFT substrate or the CF substrate and the step of producing the panel.

As the method of forming the constituent members constituting an electronic device, a common method is adopted and a photolithography method, an etching method, a vapor deposition method, or the like is used.

Also, the method of forming an organic EL panel (OLED) includes, for example, a step of forming an electrode, a hole transporting layer, a light emitting layer, an electron transporting layer, and the like on a substrate and a step of attaching the substrate on which the electron transporting layer and the like have been formed with an opposing substrate. In this case, the removing step is conducted, for example, after the step of attaching the substrate with the opposing substrate or between the step of forming the electron transporting layer and the like on the substrate and the step of attaching the substrate with the opposing substrate.

Furthermore, the steps of forming a solar cell include, for example, a step of forming an electrode, a p-n organic semiconductor layer, and the like on the substrate. In this case, the removing step is conducted, for example, after the step of forming the p-n organic semiconductor layer and the like on the substrate.

In the present embodiment, in the forming step, since the resin layer 12 is heated to the third temperature exceeding the second temperature, the crosslinking reaction of silicone moiety of the polyimide silicone proceeds. In the resin composition of the present invention, decomposition of the silicone moiety is suppressed and hence generation of low molecular gases can be inhibited. Accordingly, foaming of the resin layer 12 can be suppressed. Moreover, when the crosslinking reaction of the silicone moiety proceeds upon heating up to the third temperature, since the resin layer 12 is cured to decrease the adhesive property, the resin layer 12 can be easily peeled off from the substrate 22 in the removing step.

In the removing step, as a method of peeling the resin layer 12 from the substrate 22, a common method is used. For example, there is a method of inserting a razor or the like between the resin layer 12 and the substrate 22 at a corner part of the structure 20 to make a gap and then separating the substrate 22 side from the fixing plate 14 side.

### EXAMPLES

The following will describe the present invention specifically with reference to Examples and the like but the present invention should not be construed as being limited to these examples.

### Synthesis of Polyimide Silicone

### Synthetic Example 1

Into a flask equipped with a stirrer, a thermometer, and a nitrogen substitution apparatus were charged 4,4′-hexafluoropropylidene bisphthalic acid dianhydride (88.8 g, 0.2 mol) and 500g of cyclohexanone. Then, a solution containing diaminovinylsiloxane (243.5 g, 0.18 mol) represented by the following formula (13) and 4,4′-diaminodiphenyl ether (4.0 g, 0.02 mol) dissolved in 200 g of cyclohexanone was added dropwise into the flask with regulation so that the temperature of the reaction system did not exceed 50° C. After the completion of the dropwise addition, the whole was further stirred at room temperature for 10 hours. Then, to the flask, a reflux condenser fitted with a water acceptor was attached and then 70 g of xylene was added thereto. When the temperature was elevated to 150° C. and the temperature was kept for 6 hours, a yellowish brown solution was obtained. After the thus obtained solution was cooled to room temperature (25° C.), it was poured into methanol. When the resulting precipitate was dried, a polyimide silicone having a vinyl group as a side chain, which was composed of two kinds of repeating units as represented by the following formula (14), was obtained. In the silicone moiety of the resin, the number of the vinyl groups is 50% relative to the number of the silicon atoms.

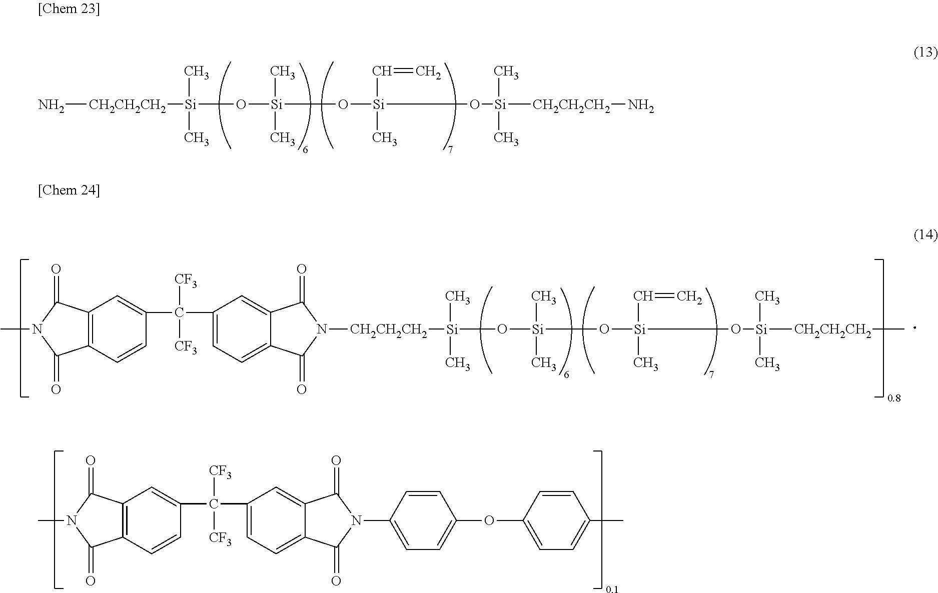

When an infrared absorption spectrum of the obtained resin was measured, absorption based on unreacted polyamic acid did not appear and absorption based on imide group was confirmed at 1,780 cm⁻¹ and 1,720 cm⁻¹. When weight-average molecular weight of the resin was measured in terms of polystyrene by gel permeation chromatography (GPC) using tetrahydrofuran as a solvent, it was 62,000. The resin is referred to as a polyimide silicone (a).

### Synthetic Example 2

The polyimide silicone (a) (1106.38 g) obtained in Synthetic Example 1 was cooled to room temperature, and thereafter, thereto was added hydrotriethoxysilane (1.3 mol) by portions. After the whole amount was added, thereto was added 0.05 g of chloroplatinic acid (H₂PtCl₆.H₂O) as a hydrosilylation catalyst, followed by reacting for 5 hours. After the reaction, a polyimide silicone having an alkoxysilyl group as a side chain, which was composed of two kinds of repeating units represented by the following formula (15), was obtained. The resin has an alkoxysilyl group as a side chain instead of vinyl group in a silicone moiety thereof. The resin is referred to as a polyimide silicone (b).

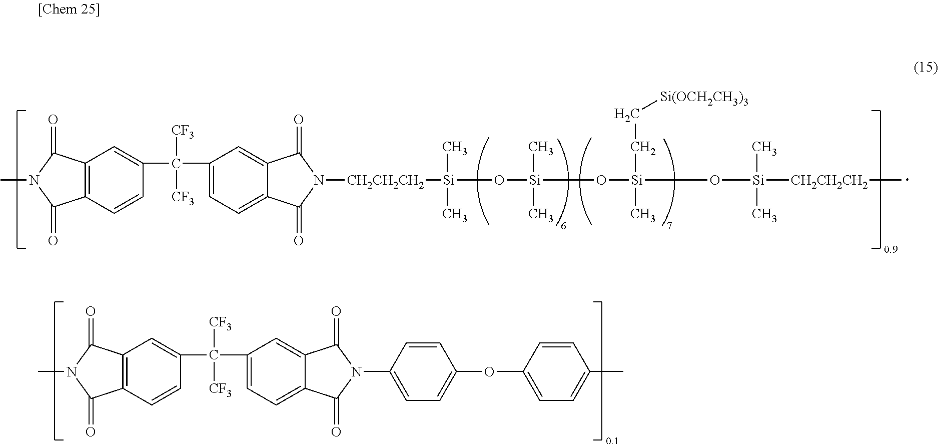

### Synthetic Example 3

In Synthetic Example 3, a polyimide silicone having a vinyl group as a side chain, which was composed of two kinds of repeating units represented by the following formula (17), was obtained in the same manner as in Synthetic Example 1 except that a diaminovinylsiloxane (267.6 g, 0.18 mol) represented by the following formula (16) and having a high vinyl group content was used in place of the diaminovinylsiloxane represented by the above formula (13). In the silicone moiety of the resin, the number of the vinyl groups is 150% relative to the number of the silicon atoms.

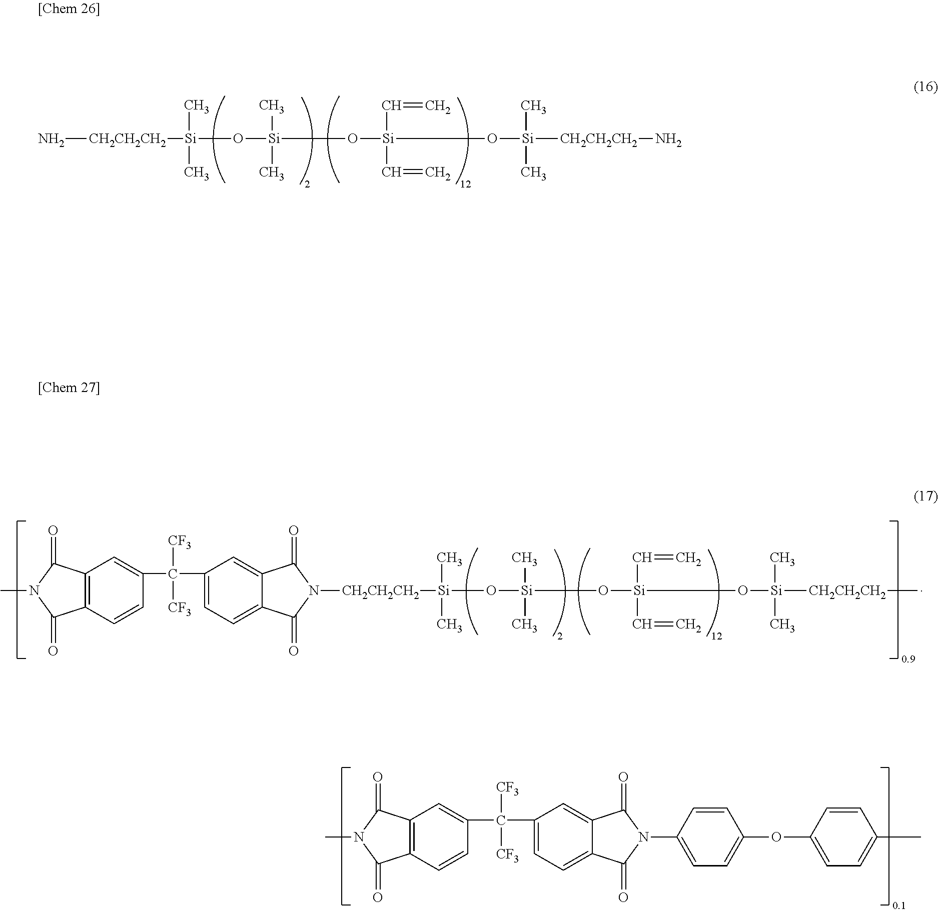

When an infrared absorption spectrum of the obtained resin was measured, absorption based on unreacted polyamic acid did not appear and absorption based on the imide group was confirmed at 1,780 cm⁻¹ and 1,720 cm⁻¹. When weight-average molecular weight of the resin was measured in the same manner as in Synthetic Example 1, it was 67,000. The resin is referred to as a polyimide silicone (c). The resin has a vinyl group in a silicone moiety thereof.

### Synthetic Example 4

In Synthetic Example 4, a polyimide silicone composed of two kinds of repeating units represented by the following formula (19) was obtained in the same manner as in Synthetic Example 1 except that diaminodimethylsiloxane (228.4 g, 0.18 mol) represented by the following formula (18) and containing no vinyl group was used in place of the diaminovinylsiloxane represented by the above formula (13).

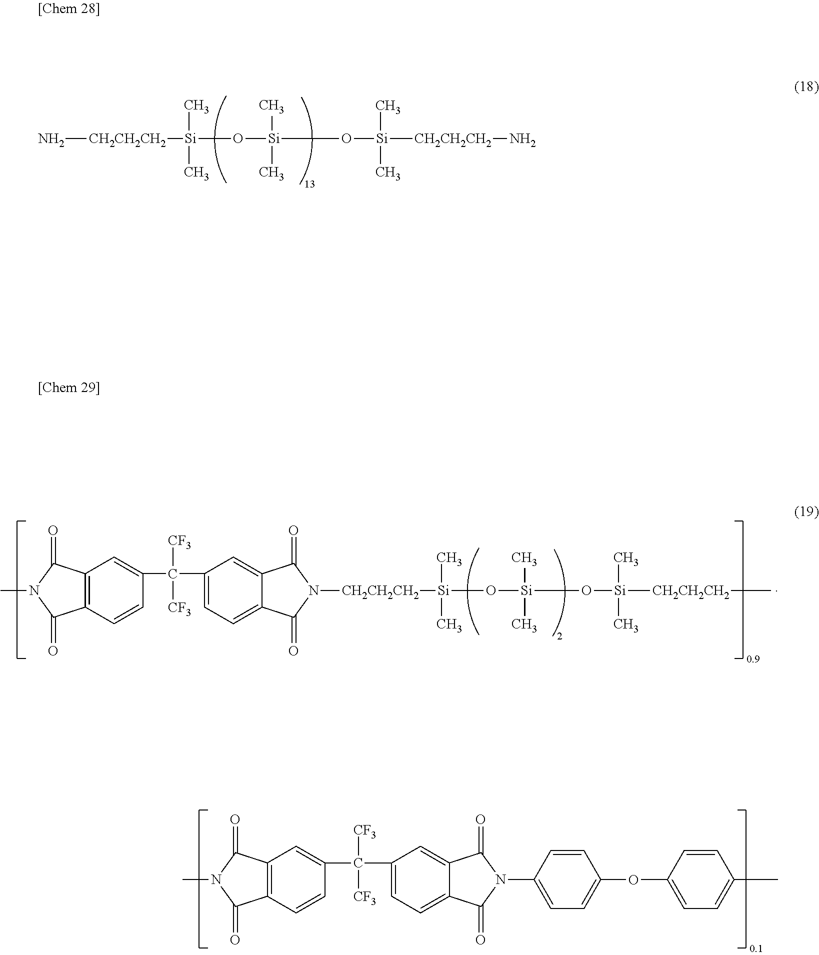

When an infrared absorption spectrum of the obtained resin was measured, absorption based on unreacted polyamic acid did not appear and absorption based on the imide group was confirmed at 1,780 cm⁻¹ and 1,720 cm⁻¹. When weight-average molecular weight of the resin was measured in the same manner as in Synthetic Example 1, it was 59,000. The resin is referred to as a polyimide silicone (d). The resin does not have any crosslinking group and has only a methyl group that is a crosslinking point, in a silicone moiety thereof.

### (Preparation of Resin Composition)

The polyimide silicone, peroxide (curing agent), and solvent shown in Table 1 were mixed in a blend ratio shown in Table 1 to prepare a resin composition. Incidentally, the symbols in the column of “Kind” of the peroxide in Table 1 represent the following peroxides, respectively.

(I) t-buthyl hydroperoxide (for high-temperature curing)
(II) 1,6-bis(t-butylperoxycarbonyloxy)hexane (for low-temperature curing)

TABLE 1

| | | Composition | | | | | | Solvent drying | |
|---|---|---|---|---|---|---|---|---|---|
| | | Polyimide | | Peroxide | | | | temperature | Product |
| | | silicone resin | part | (curing agent) | part | Solvent | part | (° C.) | substrate |
| Example | 1 | a | 100 | — | — | PGMEA | 200 | 150 | polyimide |
| | 2 | b | 100 | — | — | PGMEA | 200 | 150 | polyimide |
| | 3 | d | 100 | I | 5 | PGMEA | 200 | 150 | polyimide |
| | 4 | a | 100 | II | 3 | MIBK | 250 | 130 | polyimide |
| | 5 | c | 100 | II | 3 | MIBK | 250 | 130 | polyimide |
| Comparative | 1 | d | 100 | II | 3 | PGMEA | 200 | 150 | polyimide |
| Example | | | | | | | | | |

### (Production of Structure and Performance Evaluation Thereof)

### (Production of Laminate)

First, as a fixing plate, one obtained by washing and cleaning a glass plate of 25×75 mm square having a plate thickness of 0.7 mm and a linear expansion coefficient of 38×10⁻⁷/° C. (AN100, manufactured by ASHAHI GLASS Co., Ltd) was prepared.

Then, each resin composition shown in Table 1 was applied on the prepared glass plate by a spin coater and was heated at 80° C. for 30 minutes under atmospheric pressure and further at a temperature at which the solvent was sufficiently vaporized for 1 hour, thereby forming a polyimide silicone film (resin layer). The thickness of the resin layer was made 10 μm.

### (Production of Structure)

A substrate was press-bonded onto the resin layer of the obtained laminate at room temperature under atmospheric pressure to obtain a structure. As the substrate, a polyimide film having a plate thickness of 0.05 mm (KAPTON 200HV, manufactured by Du Pont-Toray Co., Ltd.) was used.

### (Performance of Structure)

### (1) Initial Peel Strength

The peel strength between the substrate and the resin layer in the obtained each structure was measured by a 90° peeling test (in accordance with JIS Z0237). The results of the measurement are shown in Table 2.

### (2) Heat Resistance

The obtained each structure was heated for 2 hours in a hot-air circulating oven heated at 350° C. (that corresponds to the temperature for forming an amorphous silicon layer that constitutes a thin-layer transistor). After taken out of the oven and cooled to room temperature, the presence or absence of foaming attributable to thermal decomposition and gasification of the resin layer and the presence or absence of lifting of the substrate from the resin layer were visually inspected. The results of the inspection are shown in Table 2. Incidentally, upon heating at 400° C. that corresponds to the temperature for forming an oxide semiconductor layer for 1 hour, the peel strength after heating was equal to the peel strength after heating at 350° C.

(3) Peel Strength after Heating

The peel strength between the substrate and the resin layer in each structure after the heat resistance test was measured by a 90° peeling test. Also, the presence of transference of the resin to the substrate after peeling was visually inspected. The results are shown in Table 2.

TABLE 2

| | | | Peel strength | Peel strength | | Resin |
|---|---|---|---|---|---|---|
| | | Initial peel | after heating at | after heating at | Foaming, | transference |
| | | strength | 350° C. for 1 h | 400° C. for 1 h | lifting, | to product |
| | | (N/25 mm) | (N/25 mm) | (N/25 mm) | exfoliation | substrate |
| Ex. | 1 | 1.6 | 1.2 | 1.2 | absence | absence |
| | 2 | 1.5 | 1.2 | 1.5 | absence | absence |
| | 3 | 1.7 | 1.3 | 1.4 | absence | absence |
| | 4 | 1.0 | 1.2 | 1.2 | absence | absence |
| | 5 | 1.0 | 0.3 | 0.4 | absence | absence |
| Comp. | 1 | 1.7 | impossible to | impossible to | absence | presence |
| Ex. | | | peel | peel | | |

From the results of Example 1, it is understood that a resin layer excellent in adhesive property is obtained and a good initial peel strength is obtained by drying the resin composition at low temperature to form a resin layer.

Also, form the results of Example 1, it is understood that the adhesive property of the resin layer is decreased by thermal crosslinking of the vinyl group and thus, after heating, the resin layer can be easily peeled off from the substrate.

From the results of Example 1, it is understood that the foaming of the resin layer can be suppressed and the lifting of the substrate from the resin layer can be suppressed by thermal crosslinking of the vinyl group.

From the results of Example 2, it is understood that the same effects as in Example 1 are also obtained by thermal crosslinking of the alkoxysilyl group instead of the thermal crosslinking of the vinyl group.

From the results of Example 3, it is understood that the same effects as in Example 1 are also obtained by thermal crosslinking of the methyl group in the presence of a radical instead of the thermal crosslinking of the vinyl group.

From the results of Examples 4 and 5, it is understood that the same effects as in Example 1 are obtained when the remaining vinyl group is present to some degree even in the case where the crosslinking of the vinyl group proceeds to some extent at the time of forming the resin layer. Also, the initial peel strength can be controlled by crosslinking the vinyl group to some extent at the time of forming the resin layer and thus the correction of positional relationship between the resin layer 12 and the substrate 22 or the like becomes easy.

From the results of Comparative Example 1, in the case where the crosslinking site is a crosslinking point, crosslinking becomes insufficient when a peroxide having a temperature of a half-life of ten hours is lower than the first temperature is used and detachability from the base material becomes worse.

From the comparison between Example 5 and Example 4, it is understood that the peel strength after heating can be decreased by increasing the crosslinking density.

### (Production of Electronic Device)

A process for producing a top emission type OLED by using the structure obtained in Example 4 will be described.

The structure of Example 4 (hereinafter referred to as “structure A”) flows through usual steps for OLED back plate and flows through a step of forming transparent electrode, a step of depositing a hole transporting layer, a light emission layer, an electron transporting layer, and the like, and a step of applying a barrier layer.

The structure A having a back plate for OLED formed thereon and a structure B having a front plate for OLED (for example, a glass or a resin such as PEN•PES), which has a high visual light transmittance, are attached to each other through a sealing material so that each fixing plate comes outward, thereby obtaining a cell containing the structures A and B.

Subsequently, after the structure B side is fixed on a stage by vacuum suction, a stainless steel-made knife having a thickness of 0.1 mm is inserted between the substrate and the resin layer of a corner part of the structure A to make a gap. Then, after the fixing plate of the structure A is fixed by vacuum suction by nine vacuum sucking pads, the vacuum sucking pads are elevated one by one starting from one present nearer to the inserted position of the knife. As a result, the laminate on the structure A side can be peeled off from the substrate.

Then, after the substrate on the structure A side is fixed on a stage by vacuum suction, a stainless steel-made knife having a thickness of 0.1 mm is inserted between the substrate and the resin layer of a corner part of the structure B to make a gap. Then, after the fixing plate of the structure B is fixed by vacuum suction by twelve vacuum sucking pads, the vacuum sucking pads are elevated one by one starting from one present nearer to the inserted position of the knife. As a result, the laminate on the structure B side can be peeled off from the substrate.

Thus, the laminates for reinforcement can be peeled off from the cell containing the structures A and B. Accordingly, a cell having a thickness of 0.31 mm is obtained. Thereafter, OLED is formed by carrying out module formation steps. OLED thus obtained does not result in problems on properties.

While the present invention has been described in detail and with reference to specific embodiments thereof, it will be apparent to one skilled in the art that various changes and modifications can be made therein without departing from the spirit and scope of the invention.

The present application is based on Japanese Patent Application No. 2010-234924 filed on Oct. 19, 2010, and the contents are incorporated herein by reference.

### DESCRIPTION OF REFERENCE NUMERALS AND SIGNS

10 Laminate
12 Resin layer
14 Fixing plate
20 Structure
22 Substrate

1. A resin composition comprising: a polyimide silicone having, in a silicone moiety therein, a crosslinking site at which a crosslinking reaction occurs upon heating at a second temperature that exceeds a first temperature; and a solvent which vaporizes upon drying at the first temperature that is lower than the second temperature.

2. The resin composition according to claim 1, wherein the polyimide silicone has a crosslinking group as the crosslinking site.

3. The resin composition according to claim 2, wherein the crosslinking group is an alkenyl group having an unsaturated double bond at a terminal thereof.

4. The resin composition according to claim 3, wherein the resin composition further comprises a peroxide that forms a radical upon heating up to the first temperature and
the crosslinking group is a crosslinking site at which crosslinking occurs in the presence of the radical.

5. The resin composition according to claim 2, wherein the crosslinking group is an alkoxysilyl group and is a crosslinking site at which crosslinking occurs through a condensation reaction upon heating at the second temperature.

6. The resin composition according to claim 1, wherein the polyimide silicone has a crosslinking point as the crosslinking site,
the resin composition further comprises a peroxide that forms a radical upon heating at the second temperature, and
the crosslinking point is a site at which crosslinking occurs in the presence of the radical.

7. The resin composition according to claim 6, wherein the crosslinking point is an alkyl group that is bonded to a silicon atom.

8. A laminate comprising a resin layer and a fixing plate that fixes the resin layer,
wherein the resin layer is obtained by heating the resin composition described in claim 1 at the first temperature and drying it.

9. A process for producing a laminate containing a resin layer and a fixing plate that fixes the resin layer, which comprises
a step of forming the resin layer by heating the resin composition described in claim 1 at the first temperature and drying it.

10. A process for producing a structure containing a substrate, a resin layer that supports the substrate and a fixing plate that fixes the resin layer, which comprises
a step of forming the resin layer by heating the resin composition described in claim 1 at the first temperature and drying it.

11. A process for producing an electronic device comprising: a forming step of forming at least a part of constituent members constituting the electronic device on the substrate of the structure obtained by the producing process described in claim 10; and a removing step of removing the resin layer and the fixing plate by peeling off the resin layer from the substrate on which the at least a part of constituent members is formed,
wherein, in the forming step, the resin layer is heated up to a third temperature that exceeds the second temperature and the crosslinking site of the polyimide silicone is crosslinked.

12. A process for producing an electronic device comprising:
a step of applying on a fixing plate a resin composition comprising a polyimide silicone having a crosslinking site in a silicone moiety therein and a solvent, and subsequently heating them at a first temperature to volatilize the solvent, to obtain a laminate comprising the fixing plate and a resin layer,
a step of heating at a second temperature that exceeds the first temperature, to obtain a laminate in which the resin layer is crosslinked,
a step of laminating a substrate on the resin layer side of the laminate in which the resin layer is crosslinked, to obtain a structure comprising the substrate, the resin layer that supports the substrate and the fixing plate that fixes the resin layer,
a forming step of heating up to a third temperature that exceeds the second temperature to cause crosslinking the crosslinking site of the polyimide silicone and to form at least a part of structural members constituting the electronic device on the substrate of the structure, and
a removing step of removing the resin layer and the fixing plate by peeling off the resin layer from the substrate on which the at least a part of structural members is formed, in this order.

13. A process for producing an electronic device comprising:
a step of laminating on a fixing plate a resin layer obtained by heating a resin composition comprising a polyimide silicone having a crosslinking site in a silicone moiety therein and a solvent at a first temperature to volatilize the solvent, to obtain a laminate comprising the fixing plate and the resin layer,
a step of heating at a second temperature that exceeds the first temperature, to obtain a laminate in which the resin layer is crosslinked,
a step of laminating a substrate on the resin layer side of the laminate, to obtain a structure comprising the substrate, the resin layer that supports the substrate and the fixing plate that fixes the resin layer,
a forming step of heating up to a third temperature that exceeds the second temperature to cause crosslinking the crosslinking site of the polyimide silicone and to form at least a part of structural members constituting the electronic device on the substrate of the structure, and
a removing step of removing the resin layer and the fixing plate by peeling off the resin layer from the substrate on which the at least a part of structural members is formed, in this order.
